(19) United States
(12) Patent Application Publication
(10) Pub. No.: US 2016/0035794 A1
(43) Pub. Date: Feb. 4, 2016

(54) PHOTOCHARGE STORAGE ELEMENT AND DEVICES INCLUDING THE SAME

(71) Applicant: Samsung Electronics Co., Ltd., Suwon-si (KR)

(72) Inventors: Yun Jeong KIM, Seoul (KR); Sang Chul SUL, Suwon-si (KR); Chung Kun SONG, Busan (KR); Myung Won LEE, Hwaseong-si (KR); Tae Yon LEE, Seoul (KR); Gi Seong RYU, Busan (KR); Seung Hyeon JEONG, Busan (KR); Chang Min JEONG, Busan (KR); Hyun Ji JO, Busan (KR)

(73) Assignee: Dong-A University Research Foundation For Industry-Academy Cooperation, Saha-gu (KR)

(21) Appl. No.: 14/812,264

(22) Filed: Jul. 29, 2015

(30) Foreign Application Priority Data
Jul. 31, 2014 (KR) 10-2014-0098496

(51) Int. Cl. H01L 27/30; H04N 5/225; G01J 1/44; H04N 5/378; H01L 51/42; H01L 51/44

(52) U.S. Cl. CPC H01L 27/307; H01L 51/428; H01L 51/441; H01L 51/424; G01J 1/44; H04N 5/378; H04N 5/2253; G01J 2001/446

(57) ABSTRACT

A photocharge storage element includes a gate insulator formed on a gate electrode, a channel formed on the gate insulator between a source electrode and a drain electrode, and an organic photoelectric conversion element formed on the channel. The organic photoelectric conversion element generates photocharges in response to light. The channel accumulates the photocharges generated by the organic photoelectric conversion element. The photocharges accumulated in the channel are read out from the channel in response to a voltage between the source electrode and the drain electrode.

### CROSS-REFERENCE TO RELATED APPLICATIONS

This application claims priority under 35 U.S.C. §119(a) from Korean Patent Application No. 10-2014-0098496 filed on Jul. 31, 2014, the disclosure of which is hereby incorporated by reference in its entirety.

### BACKGROUND

1. Technical Field

At least one embodiment of the present disclosure relates to an organic light storage element, and in one embodiment, more particularly, to an organic light storage element including a channel for reducing or minimizing dark current by separately performing charge accumulation and charge transfer according to a voltage of a transfer control signal operating for a short time, and/or to devices including the same.

2. Description of the Related Art

A photodiode is an example of a photoelectric conversion element or a photodetector which converts light energy into current or voltage. Photodiodes have a P-N junction or a P-I-N junction. The photodiodes generate free electrons and holes using the photoelectric effect. The photodiodes are generally used in complementary metal-oxide-semiconductor (CMOS) image sensors due to functions of photoelectric conversion or photodetection. CMOS image sensors are image sensors manufactured using CMOS processes and include a pixel array including a plurality of pixel sensors. Each of the plurality of pixel sensors include a photodetector such as the photodiode and may also include an amplifier.

Pixel signals that are output from the pixel array are converted into digital signals through various processes such as correlated double sampling (CDS) and analog-to-digital conversion. The digital signals are processed in an image signal processor and then displayed on a display.

The quality of images displayed on the display may be determined depending on the performance of a pixel sensor including the photodiode. Accordingly, there has been a lot of research and development into improved performance of pixel sensors.

Among recent research on reducing the size of a CMOS image sensor, there has been an approach for replacing a silicon photodiode with an organic photoelectric conversion element. However, dark current may increase because of thermally generated charges at an interface of the organic photoelectric conversion element.

### SUMMARY

Some embodiments of the present disclosure may provide an organic light storage element including a channel for reducing or minimizing dark current by separately performing charge accumulation and charge transfer in terms of time according to a voltage of a transfer control signal operating for a short time.

According to some embodiments of the present disclosure, there is provided a photocharge storage element including a gate insulator formed on a gate electrode, a channel formed on the gate insulator between a source electrode and a drain electrode, and an organic photoelectric conversion element formed on the channel in order to generate photocharges in response to light. The channel may accumulate the photocharges generated by the organic photoelectric conversion element.

The photocharges accumulated in the channel may be read out from the channel in response to a voltage between the source electrode and the drain electrode. Alternatively, the photocharges accumulated in the channel may be read out from the channel in response to a difference between a voltage applied to one electrode among the source electrode and the drain electrode and a voltage applied to the gate electrode.

When the channel is an N-type, a conduction band of the channel may be higher than that of the organic photoelectric conversion element, and a valence band of the channel may be higher than that of the organic photoelectric conversion element, on the basis of a vacuum level. When the channel is a P-type, the conduction band of the channel may be lower than that of the organic photoelectric conversion element, and the valence band of the channel may be lower than that of the organic photoelectric conversion element, on the basis of a vacuum level.

The photocharge storage element may further include an electrode formed on the organic photoelectric conversion element. The organic photoelectric conversion element may include a plurality of organic layers having different energy levels. The plurality of organic layers may generate the photocharges based on a voltage applied between the gate electrode and the electrode, and may move the photocharges to the channel.

The electrode may be used as a cathode when photoelectrons among the photocharges generated in the organic layers are collected in the channel. The electrode may be used as an anode when photoholes among the photocharges generated in the organic layers are collected in the channel. The gate electrode, the gate insulator, the source electrode, the drain electrode, and the channel may form an organic field-effect transistor.

The photocharge storage element may further include a semiconductor substrate which is formed below the gate electrode and includes a connecting node, and may also include a via configured to connect one electrode among the source electrode and the drain electrode with the connecting node. The gate insulator may be formed to surround the gate electrode.

According to other embodiments of the present disclosure, there is provided an image sensor including a photocharge storage element and a row driver configured to control an operation of the photocharge storage element. The photocharge storage element may include a gate insulator formed on a gate electrode, a channel formed on the gate insulator between a source electrode and a drain electrode, and an organic photoelectric conversion element formed on the channel in order to generate photocharges in response to light.

An energy band of the channel may be higher than that of the organic photoelectric conversion element when the channel is an N-type. The energy band of the channel may be lower than that of the organic photoelectric conversion element when the channel is a P-type.

According to further embodiments of the present disclosure, there is provided a portable electronic device including an image sensor and a processor configured to control an operation of the image sensor. The image sensor may include a photocharge storage element and a row driver configured to control an operation of the photocharge storage element. The photocharge storage element may include a gate insulator formed on a gate electrode, a channel formed on the gate insulator between a source electrode and a drain electrode, and an organic photoelectric conversion element formed on the channel in order to generate photocharges in response to light.

### BRIEF DESCRIPTION OF THE DRAWINGS

The above and other features and advantages of the present disclosure will become more apparent by describing in detail example embodiments thereof with reference to the attached drawings in which:

FIG. 1 is a cross-sectional view of a photocharge storage element including a channel according to some embodiments of the present disclosure;

FIG. 2A is a cross-sectional view of a photocharge storage element including a channel according to other embodiments of the present disclosure;

FIG. 2B is a cross-sectional view of a photocharge storage element including a channel according to further embodiments of the present disclosure;

FIGS. 3A and 3B are diagrams of a photocharge generation region illustrated in FIGS. 1 through 2B according to some embodiments of the present disclosure;

FIG. 4 is a conceptual diagram for explaining a procedure in which a photocharge generated in an organic photoelectric conversion element illustrated in FIG. 3 is moved to and stored in a channel;

FIG. 5 is a conceptual diagram illustrating voltages applied to a photocharge storage element and an operation of the photocharge storage element according to some embodiments of the present disclosure;

FIG. 6 is a conceptual diagram for explaining an operation of a photocharge storage element according to some embodiments of the present disclosure;

FIG. 7 is a circuit diagram of a photocharge storage element including an organic photoelectric conversion element and a pixel circuit, which are illustrated in FIG. 1, 2A, or 2B, according to some embodiments of the present disclosure;

FIG. 8 is a circuit diagram of a photocharge storage element including the organic photoelectric conversion element and the pixel circuit, which are illustrated in FIG. 1, 2A, or 2B, according to other embodiments of the present disclosure;

FIG. 9 is a circuit diagram of a photocharge storage element including the organic photoelectric conversion element and the pixel circuit, which are illustrated in FIG. 1, 2A, or 2B, according to further embodiments of the present disclosure;

FIG. 10 is a block diagram of an image processing system including the photocharge storage element illustrated in FIG. 1 or 2B according to some embodiments of the present disclosure; and

FIG. 11 is a block diagram of a portable electronic device including the image processing system illustrated in FIG. 10 according to some embodiments of the present disclosure.

### DETAILED DESCRIPTION OF THE EMBODIMENTS

The present disclosure now will be described more fully hereinafter with reference to the accompanying drawings, in which embodiments of the present disclosure are shown. The present disclosure may, however, be embodied in many different forms and should not be construed as limited to the embodiments set forth herein. Rather, these embodiments are provided so that this disclosure will be thorough and complete, and will fully convey the scope of the present disclosure to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

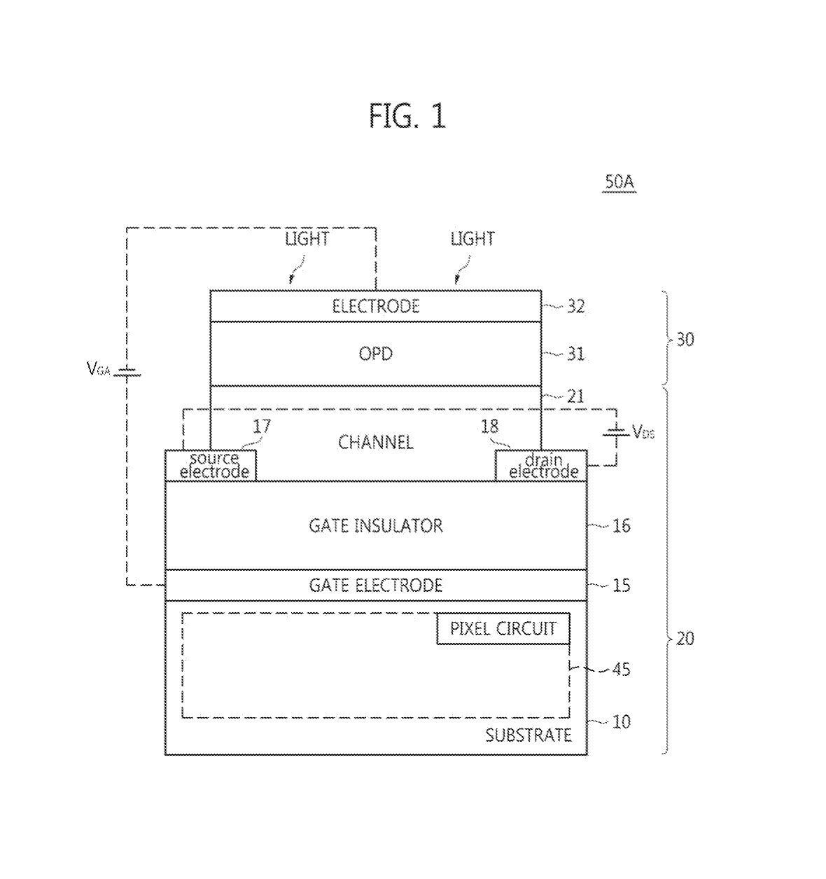

FIG. 1 is a cross-sectional view of a photocharge storage element 50A including a channel 21 according to some embodiments of the present disclosure. The cross-sectional view illustrated in FIG. 1 is taken on the basis of a source electrode 17 and a drain electrode 18. Referring to FIG. 1, the photocharge storage element 50A may include a photocharge generation region 30 and a photocharge storing region 20.

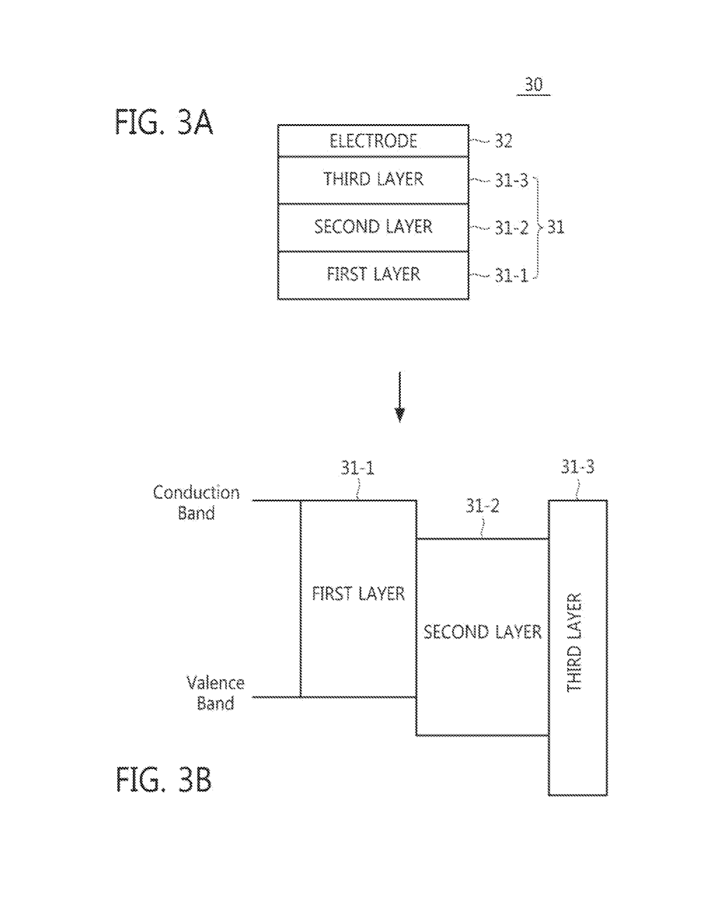

The photocharge generation region 30 may include an organic photoelectric conversion element 31 and an electrode 32. The organic photoelectric conversion element 31 may be implemented as an organic photodiode (OPD) or an organic photo transistor. As shown in FIG. 3, the organic photoelectric conversion element 31 may include a plurality of organic layers 31-1 through 31-3. The organic photoelectric conversion element 31 may have a structure in which photocharges are generated in response to light LIGHT. At this time, the photocharges may be photoelectrons and/or photoholes.

The electrode 32 may be formed on or above the organic photoelectric conversion element 31. It will also be understood that when a layer is referred to as being “on” another layer or substrate, it can be directly on the other layer or substrate, or intervening layers may also be present. According to some embodiments, the electrode 32 may be formed of a transparent electrode such as indium tin oxide (ITO), indium zinc oxide (IZO), or zinc oxide (ZnO). Alternatively, the electrode 32 may be formed of aluminum (Al). At this time, the electrode 32 may have a structure allowing the light LIGHT to be incident on the organic photoelectric conversion element 31.

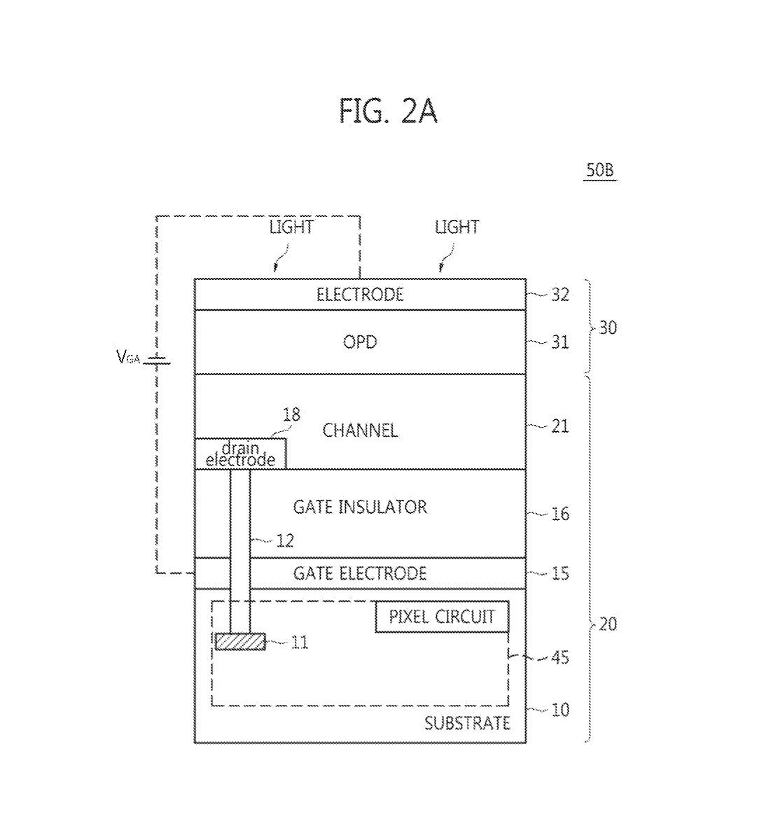

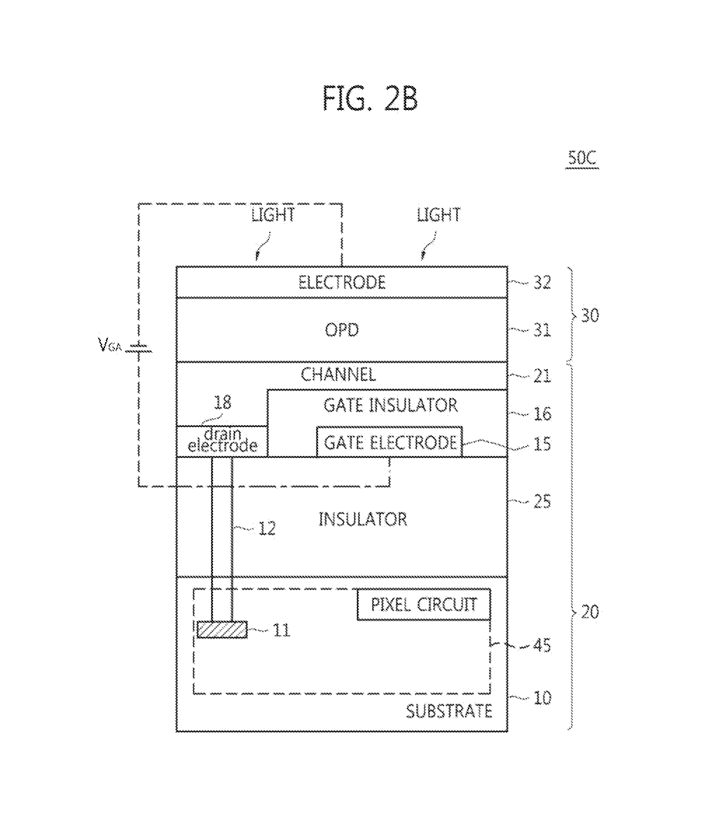

FIGS. 3A and 3B are a diagram of the photocharge generation region 30 illustrated in FIGS. 1 through 2B according to some embodiments of the present disclosure. Referring to FIG. 1 and FIG. 3A, the organic photoelectric conversion element 31 may include the first layer 31-1, the second layer 31-2, and the third layer 31-3.

For example, the first layer 31-1 may be formed of copper (II) phthalocyanine (CuPc), the second layer 31-2 may be formed of PTCDI-C8, and the third layer 31-3 may be formed of bathocuproine (BCP). However, these materials are just examples, and the present disclosure is not restricted to the materials that each of the layers 31-1 through 31-3 is formed of. For example, the first layer 31-1 may have a thickness of 10 to 30 nm. The second layer 31-2 may have a thickness of 30 to 50 nm. The third layer 31-3 may have a thickness of 20 nm or less. When the electrode 32 is formed of aluminum (Al), the electrode 32 may have a thickness of 30 to 50 nm.

As shown in FIG. 3A, the second layer 31-2 may be formed on the first layer 31-1 and the third layer 31-3 may be formed on the second layer 31-2. The electrode 32 may be formed on the third layer 31-3.

As shown in FIG. 3B, the organic layers 31-1 through 31-3 may have different energy levels from one another. When a photocharge is a photohole, the valence band or highest occupied molecular orbital (HOMO) of the first layer 31-1 may be lower than that of the second layer 31-2 which is lower than that of the third layer 31-3 on the basis of a vacuum level. Alternatively, when the photocharge is a photoelectron, the conduction band of the first layer 31-1 may be higher than that of the second layer 31-2 which is higher than that of the third layer 31-3 on the basis of a vacuum level.

Referring to FIGS. 1 and 3A, when photoelectrons generated in each of the organic layers 31-1 through 31-3 are collected in the channel 21, the electrode 32 may be used as a cathode. When photoholes generated in each of the organic layers 31-1 through 31-3 are collected in the channel 21, the electrode 32 may be used as an anode.

Referring back to FIG. 1, the photocharge storing region 20 may include a semiconductor substrate 10, a gate electrode 15, a gate insulator 16, a source electrode 17, a drain electrode 18, and a channel (or a channel layer) 21. For example, an organic field-effect transistor may include the gate electrode 15, the gate insulator 16, the source electrode 17, the drain electrode 18, and the channel 21. The semiconductor substrate 10 may include a pixel circuit 45.

The gate electrode 15 may be formed on the semiconductor substrate 10. The gate electrode 15 may function to lead (or induce) photocharges generated in the photo-charge generation region 30 to the channel 21. The gate insulator 16 may be formed on the gate electrode 15. The gate insulator 16 may be referred to as a gate dielectric, a gate insulation layer, or a gate insulation film. The source electrode 17 and the drain electrode 18 may be formed on the gate insulator 16. The channel 21 may be formed on the gate insulator 16 between the source electrode 17 and the drain electrode 18.

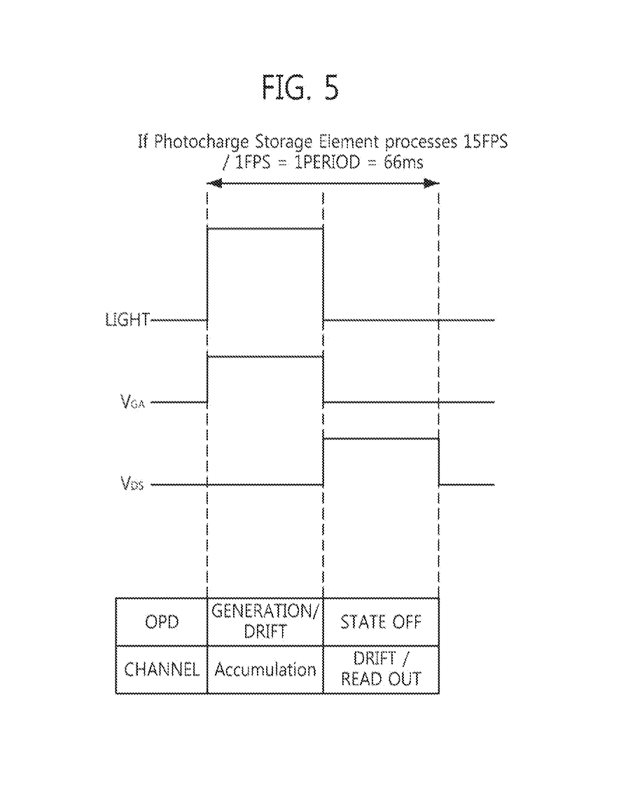

As shown in FIGS. 1 and 5, when light LIGHT is incident on the photocharge storage element 50A, a first voltage VGA may be applied between the gate electrode 15 and the electrode 32, and then a second voltage VDS may be applied between the source electrode 17 and the drain electrode 18.

As shown in FIG. 5, when light LIGHT is incident on the photocharge storage element 50A and the first voltage VGA is applied between the gate electrode 15 and the electrode 32, the organic photoelectric conversion element 31 may generate photocharges in response to the light LIGHT. At this time, an electric field may be generated between the gate electrode 15 and the electrode 32 by the first voltage VGA.

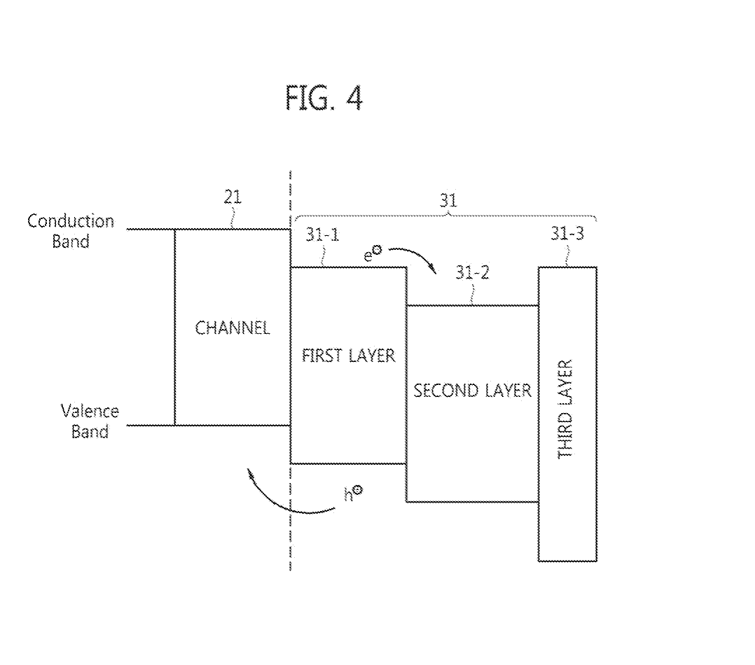

Due to the electric field, there occurs a difference between the energy level of the organic photoelectric conversion element 31 and that of the channel 21. The photocharges generated in the organic photoelectric conversion element 31 may be moved to the channel 21 due to the level difference. The movement of the photocharges to the channel 21 and the accumulation of the photocharges in the channel 21 will be described in detail with reference to FIG. 4 later. To prevent, or at least inhibit, the photocharges generated in the photo-charge generation region 30 from being transferred to the gate electrode 15 due to the first voltage VGA, the gate insulator 16 may electrically insulate the organic photoelectric conversion element 31 from the gate electrode 15.

When the photocharges generated in the photo-charge generation region 30 are photoelectrons, the channel 21 may be formed of an N-type organic material. When the channel 21 is formed of an N-type organic material, the conduction band of the channel 21 may be higher than that of the organic photoelectric conversion element 31, and the valence band of the channel 21 may be also higher than that of the organic photoelectric conversion element 31 on the basis of a vacuum level. Accordingly, when the channel 21 is formed of an N-type organic material, the energy band of the channel 21 may be higher than that of the organic photoelectric conversion element 31.

However, when the photocharges generated in the photo-charge generation region 30 are photoholes, the channel 21 may be formed of a P-type organic material. When the channel 21 is formed of a P-type organic material, the conduction band of the channel 21 may be lower than that of the organic photoelectric conversion element 31, and the valence band of the channel 21 may be also lower than that of the organic photoelectric conversion element 31 on the basis of a vacuum level. Accordingly, when the channel 21 is formed of a P-type organic material, the energy band of the channel 21 may be lower than that of the organic photoelectric conversion element 31.

For example, when the channel 21 is formed of a P-type organic material, the channel 21 may be formed of pentacene to a thickness of 40 to 60 μm. When the channel 21 is formed of an N-type organic material, the channel 21 may be formed of chalcopyrite to a thickness of 40 to 60 μm. For example, the organic material of the channel 21 may have a field mobility of a few 10-2 cm2/V*S. As described above, the channel 21 may be formed of a material other than the pentacene or the chalcopyrite.

The channel 21 may output the photocharges between the source electrode 17 and the drain electrode 18 through the source electrode 17 or through the drain electrode 18 in response to the second voltage VDS. For example, the photocharges accumulated in the channel 21 may be read out from the channel 21 according to the difference between the first voltage VGA and the second voltage VDS or according to the difference of the voltage of the gate electrode 15 and the voltage of the drain electrode 18.

FIG. 2A is a cross-sectional view of a photocharge storage element 50B including the channel 21 according to other embodiments of the present disclosure. The cross-sectional view illustrated in FIG. 2A is taken on the basis of the drain electrode 18. Referring to FIGS. 1 and 2A, the structure of the photocharge storage element 50B illustrated in FIG. 2 is substantially the same as that of the photocharge storage element 50A illustrated in FIG. 1, except for a connecting node 11 and a via 12.

Referring to FIG. 2A, the connecting node 11 and the via 12 may connect the drain electrode 18 with the pixel circuit 45 included in the semiconductor substrate 10. The drain electrode 18 may be connected to the connecting node 11 through the via 12. For example, the via 12 may be implemented as a vertical electrical connection, e.g., a through silicon via (TSV). Although FIG. 2A shows embodiments in which the drain electrode 18 is connected with the connecting node 11 through the via 12 when photoelectrons are collected, the source electrode 17 may be connected with the connecting node 11 through the via 12 when the photoholes are collected in other embodiments.

Referring back to FIGS. 1 and 2A, the organic photoelectric conversion element 31 may generate the photocharges in response to light LIGHT. The generated photocharges may be moved to and accumulated in the channel 21 by an electric field generated based on the first voltage VGA. The channel 21 may output the accumulated photocharges to the connecting node 11 through the drain electrode 18 and the via 12 (or through a source electrode and a via) based on the second voltage VDS.

FIG. 2B is a cross-sectional view of a photocharge storage element 50C including the channel 21 according to further embodiments of the present disclosure. The structure of the photocharge storage element 50C illustrated in FIG. 2B is different from that of the photocharge storage element 50B illustrated in FIG. 2A. In detail, an insulator 25 may be formed on the semiconductor substrate 10. The gate electrode 15, the gate insulator 16, the drain electrode 18, and the channel 21 may be formed on the insulator 25 in the photocharge storage element 50C. The gate insulator 16 may be formed to surround the gate electrode 15.

The organic photoelectric conversion element 31 may generate the photocharges in response to light LIGHT. The generated photocharges may be moved to and accumulated in the channel 21 due to an electric field generated based on the first voltage VGA that is applied between the electrode 32 and the gate electrode 15. The channel 21 may output the accumulated photocharges to the connecting node 11 through the drain electrode 18 and the via 12 (or through the source electrode and the via) based on the second voltage VDS that is applied between the source electrode and the drain electrode 18. For example, the photocharges accumulated in the channel 21 may be read out from the channel 21 according to the difference between the first voltage VGA and the second voltage VDS or according to the difference between the voltage of the gate electrode 15 and the voltage of the drain electrode 18.

FIG. 4 is a conceptual diagram for explaining a procedure in which a photocharge generated in the organic photoelectric conversion element 31 illustrated in FIG. 3 is moved to and stored in the channel 21. As shown in FIGS. 3 and 4, the organic photoelectric conversion element 31 may include a plurality of the organic layers 31-1 through 31-3 that have different energy levels.

It is assumed in the embodiments illustrated in FIG. 4 that the channel 21 is formed of pentacene, the first layer 31-1 is formed of CuPc, the second layer 31-2 is formed of PTCDI-C8, and the third layer 31-3 is formed of BCP. Referring to FIG. 4, on the basis of a vacuum level, the valence band of the pentacene of the channel 21 may be lower than that of each of the organic layers 31-1 through 31-3. In addition to, the valence band of the first layer 31-1 formed of CuPc may be lower than that of the second layer 31-2 formed of PTCDI-C8.

Accordingly, a photocharge generated in each of the organic layers 31-1 through 31-3 illustrated in FIG. 4 may be moved to the channel 21 by an electric field generated based on the first voltage VGA illustrated in FIGS. 1, 2A, and 2B based on differences in energy levels among the channel 21 and the organic layers 31-1 through 31-3. At this time, the photocharge moved to the channel 21 may be a photohole. In other embodiments, the channel may be formed of chalcopyrite to collect photoelectrons instead of photoholes. At this time, the conduction band of chalcopyrite may be higher than that of each of the organic layers 31-1 through 31-3 on the basis of a vacuum level.

FIG. 5 is a conceptual diagram illustrating voltages applied to the photocharge storage element and an operation of the photocharge storage element according to some embodiments of the present disclosure. Referring to FIGS. 1, 2A, 2B, and 5, when the first voltage VGA is applied to the gate electrode 15 and the electrode 32, the organic photoelectric conversion element 31 may generate photocharges in response to light LIGHT, and the generated photocharges may be drifted to the channel 21 due to an electric field generated based on the first voltage VGA.

When the supply of the first voltage VGA is cut off and the second voltage VDS is applied to the source electrode 17 and the drain electrode 18, the operation of the organic photoelectric conversion element 31 may be disabled, and the photocharges accumulated at the channel 21 may be read out according to the second voltage VDS or according to the difference between the voltage of the gate electrode 15 and the voltage of the drain electrode 18. Therefore, the photocharge storage element 50A, 50B, or 50C may separate the operation of the organic photoelectric conversion element 31 from the operation of the channel 21 using the first voltage VGA and the second voltage VDS.

To describe the separate operation of the photocharge storage element 50A, 50B, or 50C in detail, it is assumed that the period of the first and second voltages VGA and VDS is 66 ms and the photocharge storage element 50A, 50B, or 50C processes fifteen frames per second (FPS).

Referring to FIGS. 1 through 5, while the first voltage VGA is being cut off and the second voltage VDS is being applied, photocharges accumulated at the channel 21 may be read out to the connecting node 11 through the drain electrode 18 and the via 21 for several tens of μs since the channel 21 is an organic semiconductor material with a field mobility of a few 10-2 cm2N*S.

Alternatively, the photocharges accumulated at the channel 21 may be read out to the connecting node 11 through the source electrode 17 and the via 12 for several tens of μs. In other words, a readout time (e.g., several tens of μs) during which the photocharges are read out to the connecting node 11 through the via 12 and one of the source electrode 17 and the drain electrode 18 may be about 1/1000 of the whole operating time (e.g., 66 ms) of the photocharge storage element 50A, 50B, or 50C.

Accordingly, while the organic photoelectric conversion element 31 generates the photocharges and allows the photocharges to be moved to and accumulated at the channel 21 during the operating time (e.g., 66 ms) that is relatively longer than the readout time (e.g., several tens of μs), the channel 21 may allow the accumulated photocharges to be read out to the connecting node 11 through the via 12 and one of the source electrode 17 and drain electrode 8 during the readout time (i.e., several tens of μs) that is relatively shorter than the operating time (i.e., 66 ms).

As described above, the organic photoelectric conversion element 31 and the channel 21 may operate separately from each other, and therefore, electrons (e.g., noise) thermally generated while the photocharges are being read out to the connecting node 11 through the via 12 and one of the source electrode 17 and drain electrode 18 may be reduced due to the operation of the channel 21 with a field mobility of a few 10-2 cm2/V*S.

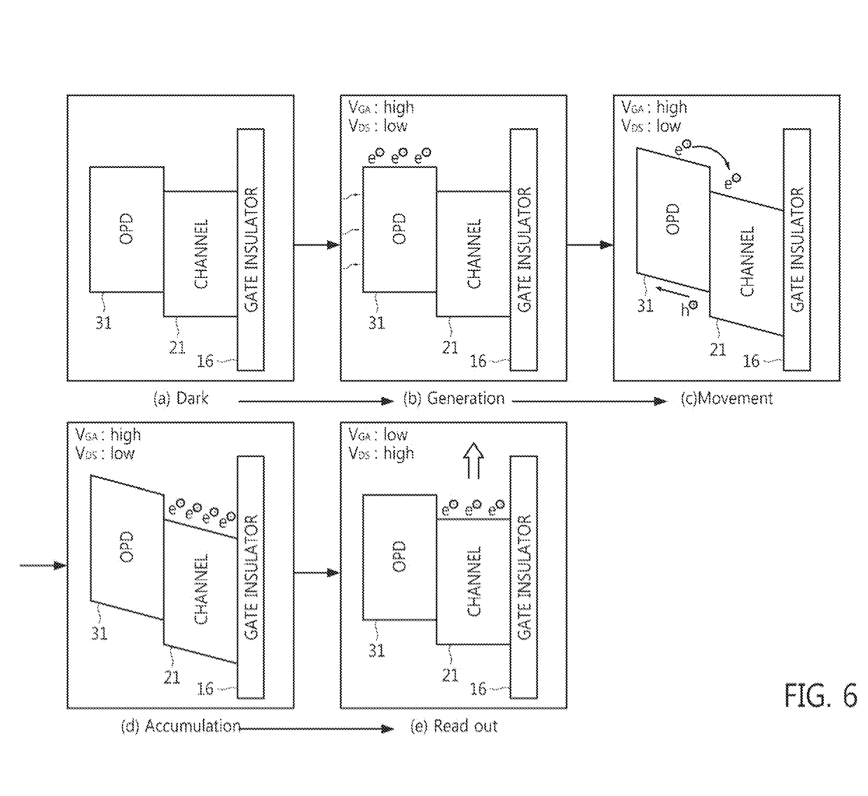

FIG. 6 is a conceptual diagram for explaining an operation of a photocharge storage element according to some embodiments of the present disclosure. Referring to FIGS. 1, 2A, 2B, 5, and 6, part (a) in FIG. 6 shows the energy levels of the organic photoelectric conversion element 31, the channel 21, and the gate insulator 16 when light LIGHT is not incident on the photocharge storage element 50A, 50B, or 50C and neither of the first and second voltages VGA and VDS is applied.

When photoelectrons are collected in the channel 21, the energy level of the organic photoelectric conversion element 31 may be higher than that of the channel 21.

Referring to part (b) in FIG. 6, when light LIGHT is incident on the photocharge storage element 50A, 50B, or 50C, the first voltage VGA may be at a high level, the second voltage VDS may be at a low level, and the organic photoelectric conversion element 31 may generate photocharges in response to the light LIGHT.

Referring to part (c) in FIG. 6, the photocharges generated in part (b) may be moved to the channel 21 due to an electric field generated by the first voltage VGA. The slope of energy level shown in part (c) in FIG. 6 may be greater than that shown in part (b) in FIG. 6. In other words, as the energy level slop increases, charges generated in the organic photoelectric conversion element 31 may be easily moved to the channel 21.

Referring to part (d) in FIG. 6, the photocharges generated while the first voltage VGA at the high level is being applied may be moved to the channel 21, and therefore, the photocharges may be accumulated at the channel 21. Parts (a) through (d) in FIG. 6 show the operations of the photocharge storage element 50A, 50B, or 50C when the first voltage VGA is at the high level and the second voltage VDS is at the low level.

Referring to part (e) in FIG. 6, when the light LIGHT is not incident on the photocharge storage element 50A, 50B, or 50C, the first voltage VGA may be at a low level, the second voltage VDS may be at a high level, and the accumulated photocharges may be read out from the channel 21.

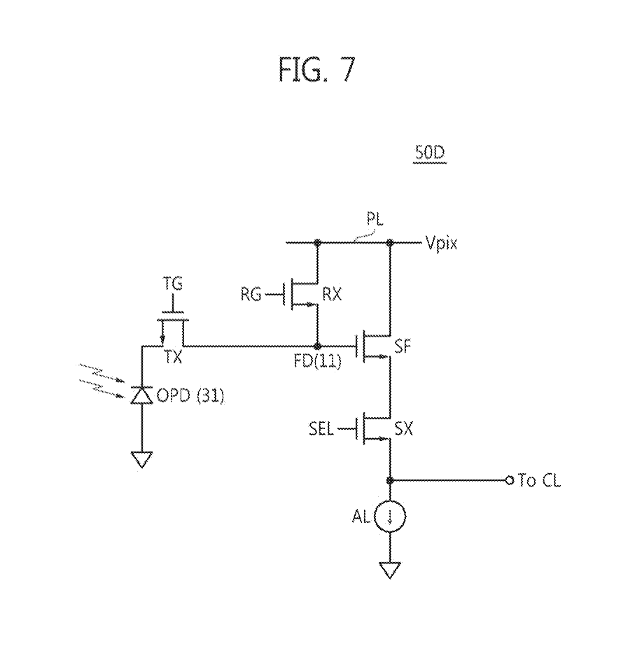

FIG. 7 is a circuit diagram of a photocharge storage element 50D including the organic photoelectric conversion element 31 and the pixel circuit 45, which are illustrated in FIG. 1, 2A, or 2B, according to some embodiments of the present disclosure. The photocharge storage element 50D may include the organic photoelectric conversion element 31 and four transistors TX, RX, SF, and SX. The pixel circuit 45 illustrated in FIG. 1, 2A, or 2B may include a transfer transistor TX, a reset transistor RX, a drive transistor SF, and a select transistor SX. A floating diffusion node FD may function as the connecting node 11 illustrated in FIG. 2A or 2B. Accordingly, the floating diffusion node FD may be connected to the via 12.

The transfer transistor TX may transfer photocharges generated in the organic photoelectric conversion element 31 to the floating diffusion node FD in response to a transfer control signal TG. The reset transistor RX may be connected between a power supply line PL supplying an operating voltage Vpix and the floating diffusion node FD in order to reset the floating diffusion node FD in response to a reset signal RG. During the reset operation, the operating voltage Vpix may be applied to the connecting node 11.

The drive transistor SF may operate in response to the voltage of the floating diffusion node FD and may function as a source follower. The select transistor SX may operate in response to a select signal SEL in order to transmit a pixel signal from the drive transistor SF to a column line CL. A bias circuit AL may function as an active load and may provide a bias current for the pixel circuit 45. The control signals TG, RG, and SEL may be output from a row driver.

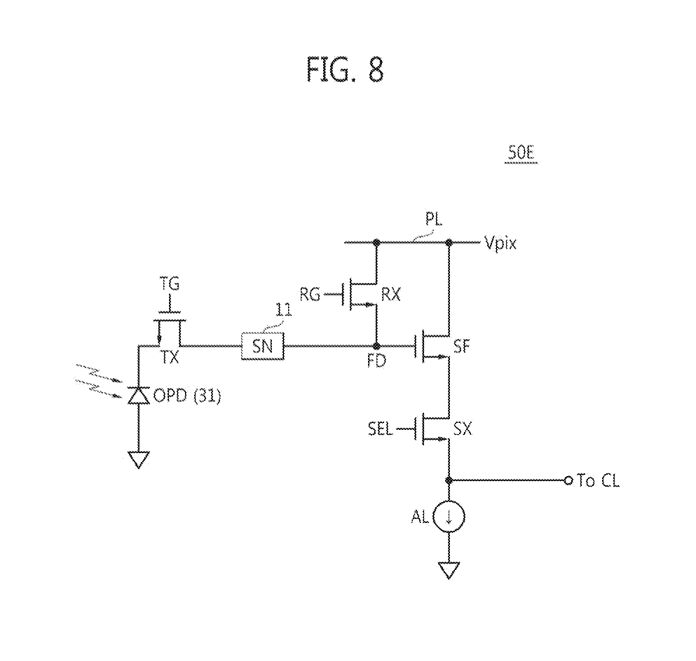

FIG. 8 is a circuit diagram of a photocharge storage element 50E including the organic photoelectric conversion element 31 and the pixel circuit 45, which are illustrated in FIG. 1, 2A, or 2B, according to other embodiments of the present disclosure. The photocharge storage element 50E may include the organic photoelectric conversion element 31, the connecting node 11, and four transistors TX, RX, SF, and SX.

The transfer transistor TX may transfer the photocharges generated in the organic photoelectric conversion element 31 to the connecting node 11 in response to the transfer control signal TG. An intermediate storage node SN may function as the connecting node 11 and may be connected in common to the floating diffusion node FD and the via 12. The intermediate storage node SN may play the role of a potential barrier. Accordingly, the voltage of the intermediate storage node SN may be fixed at a desired (or, alternatively a predetermined) value, e.g., 0 V.

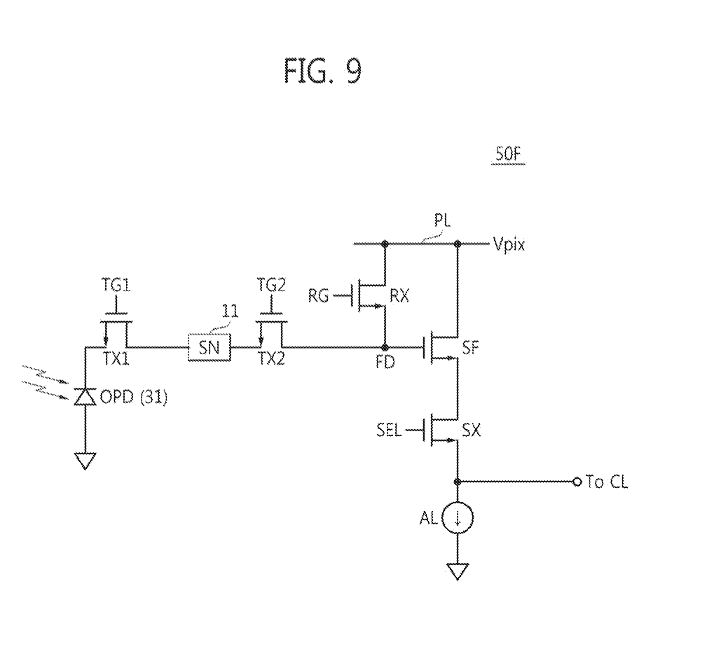

FIG. 9 is a circuit diagram of a photocharge storage element 50F including the organic photoelectric conversion element 31 and the pixel circuit 45, which are illustrated in FIG. 1, 2A, or 2B, according to further embodiments of the present disclosure. The photocharge storage element 50F may include the organic photoelectric conversion element 31, the connecting node 11, and five transistors TX1, TX2, RX, SF, and SX.

The pixel circuit 45 may also include the switch TX2 connected between the connecting node 11 and the floating diffusion node FD. At this time, the intermediate storage node SN may function as the connecting node 11 and the potential barrier. Accordingly, the voltage of the intermediate storage node SN may be fixed at a desired (or, alternatively a predetermined) value, e.g., 0 V. The intermediate storage node SN may be connected to the via 12.

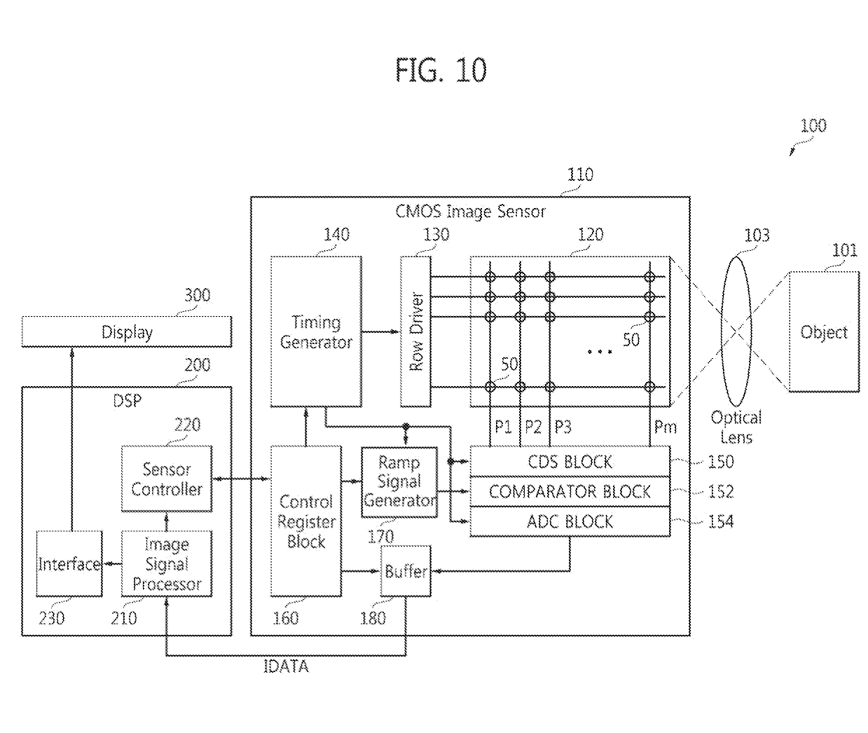

FIG. 10 is a block diagram of an image processing system 100 including the photocharge storage element 50A or 50C illustrated in FIG. 1 or 2B according to some embodiments of the present disclosure. Referring to FIGS. 1 through 10, the image processing system 100 may be implemented as a portable electronic device such as a digital camera, a camcorder, a cellular phone, a smart phone, a tablet personal computer (PC), a laptop computer, a wearable computer, or a mobile internet device (MID).

The image processing system 100 may include an optical lens 103, an image sensor 110, a digital signal processor (DSP) 200, and a display 300. The image sensor 110 may be implemented as a complementary metal-oxide-semiconductor (CMOS) image sensor or a CMOS image sensor chip.

The image sensor 110 may generate image data IDATA corresponding to an object picked up or captured through the optical lens 103. The image sensor 110 may include a pixel array 120, a row driver 130, a timing generator 140, a correlated double sampling (CDS) block 150, a comparator block 152, an analog-to-digital conversion (ADC) block 154, a control register block 160, a ramp signal generator 170, and a buffer 180.

The pixel array 120 may include a plurality of photocharge storage elements 50 arranged in a matrix. The structure and operations of the photocharge storage elements 50 are the same as those described above with reference to FIGS. 1 through 9. The row driver 130 may output a plurality of control signals for controlling the operation of the photocharge storage elements 50 to the pixel array 120 according to the control of the timing generator 140.

The timing generator 140 may control the operations of the row driver 130, the CDS block 150, the ADC block 154, and the ramp signal generator 170 according to the control of the control register block 160. The CDS block 150 may perform CDS on pixel signals P1 through Pm that are output from respective column lines formed in the pixel array 120, where “m” is a natural number.

The comparator block 152 may compare the pixel signals P1 through Pm that have been subjected to the CDS in the CDS block 150 with a ramp signal that is output from the ramp signal generator 170, and may output comparison signals. The ADC block 154 may convert the comparison signals received from the comparator block 152 into digital signals and may output the digital signals to the buffer 180.

The control register block 160 may control the operations of the timing generator 140, the ramp signal generator 170, and the buffer 180 according to the control of the DSP 200. The buffer 180 may transmit the image data IDATA corresponding to the digital signals output from the ADC block 154 to the DSP 200. The DSP 200 may include an image signal processor 210, a sensor controller 220, and an interface 230.

The image signal processor 210 may control an interface 210 and a sensor controller 220 which controls the control register block 160. According to embodiments, the image sensor 110 and the DSP 200 may be implemented in a single package, e.g., a multi-chip package (MCP). Alternatively, the image sensor 110 and the image signal processor 210 may be implemented in a single package, e.g., an MCP. The image signal processor 210 may process the image data IDATA received from the buffer 180 and may transmit the processed image data to the interface 230.

The sensor controller 220 may generate various control signals for controlling the control register block 160 according to the control of the image signal processor 210. The interface 230 may transmit the processed image data from the image signal processor 210 to the display 300. The display 300 may display the image data that is output from the interface 230. The display 300 may be a thin film transistor-liquid crystal display (TFT-LCD), a light emitting diode (LED) display, an organic LED (OLED) display, or an active-matrix OLED (AMOLED) display.

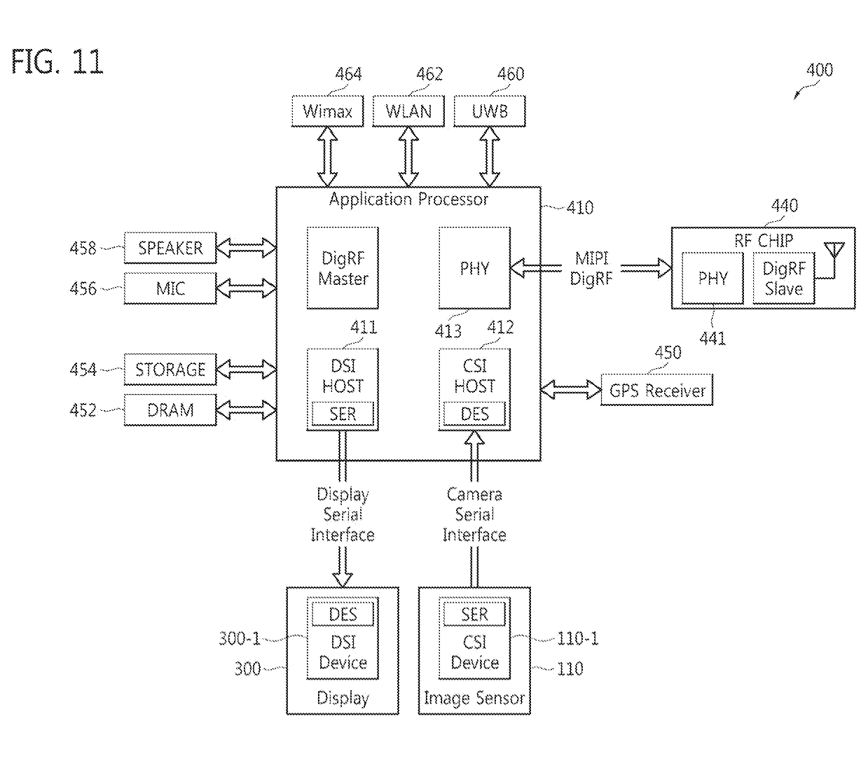

FIG. 11 is a block diagram of a portable electronic device 400 including the image processing system 100 illustrated in FIG. 10 according to some embodiments of the present disclosure. Referring to FIGS. 1 through 11, the portable electronic device 400 may use or support mobile industry processor interface (MIPI®). The portable electronic device 400 may be implemented as a digital camera, a camcorder, a personal digital assistant (PDA), a portable media player (PMP), a cellular phone, a smart phone, or a tablet PC. The portable electronic device 400 may include an application processor 410, the image sensor 110, and the display 300.

A camera serial interface (CSI) host 412 in the application processor 410 may perform serial communication with a CSI device 110-1 in the image sensor 110 through CSI. A deserializer DES and a serializer SER may be included in the CSI host 412 and the CSI device 110-1, respectively. The image sensor 110 may include the photocharge storage element 50A, 50B, or 50C that has been described with reference to FIG. 1, 2A, or 2B. For example, the image sensor 110 may be the image sensor 110 illustrated in FIG. 10.

A display serial interface (DSI) host 411 in the application processor 410 may perform serial communication with a DSI device 300-1 in the display 300 through DSI. A serializer SER and a deserializer DES may be included in the DSI host 411 and the DSI device 300-1, respectively.

The portable electronic device 400 may also include a radio frequency (RF) chip 440 communicating with the application processor 410. A physical layer (PHY) 413 in the application processor 410 and a PHY 441 in the RF chip 440 may communicate data with each other according to MIPI DigRF. The DigRF master may control an operation of the PHY 413.

The portable electronic device 400 may further include a global positioning system (GPS) receiver 450, a memory 452 such as dynamic random access memory (DRAM), a data storage 454 formed using non-volatile memory such as NAND flash memory, a microphone (MIC) 456, and/or a speaker 458. The portable electronic device 400 may communicate with external devices using at least one communication protocol or standard, e.g., ultra-wideband (UWB) 460, wireless local area network (WLAN) 462, worldwide interoperability for microwave access (Wimax) 464, or long term evolution (LTETM) (not shown).

As described above, according to some embodiments of the present disclosure, the size of a pixel may be reduced using a channel included in an organic photoelectric conversion element in a photocharge storage element and devices including the same. In addition, the operation of the organic photoelectric conversion element may be separated from the operation of the channel, so that dark current caused by charges thermally generated in the organic photoelectric conversion element can be decreased.

While the present disclosure has been particularly shown and described with reference to example embodiments thereof, it will be understood by those of ordinary skill in the art that various changes in forms and details may be made therein without departing from the spirit and scope of the present disclosure as defined by the following claims.

What is claimed is:

1. A photocharge storage element comprising:
a semiconductor substrate;
a gate electrode disposed on the semiconductor substrate;
a gate insulator disposed on the gate electrode;
a source electrode disposed on the gate insulator;
a drain electrode disposed on the gate insulator;
a channel disposed on the gate insulator, and disposed between the source electrode and the drain electrode; and
an organic photoelectric conversion element disposed on the channel, and configured to generate photocharges in response to light.

2. The photocharge storage element of claim 1, wherein the channel is configured to accumulate the photocharges.

3. The photocharge storage element of claim 2, wherein the photocharges accumulated in the channel are read out from the channel in response to a voltage between the source electrode and the drain electrode.

4. The photocharge storage element of claim 2, wherein the photocharges accumulated in the channel are read out from the channel in response to a difference between a voltage applied to one electrode among the source electrode and the drain electrode and a voltage applied to the gate electrode.

5. The photocharge storage element of claim 1, wherein if the channel is formed of an N-type material, a conduction band of the channel is higher than that of the organic photoelectric conversion element, and a valence band of the channel is higher than that of the organic photoelectric conversion element, on the basis of a vacuum level.

6. The photocharge storage element of claim 1, wherein when the channel is formed of a P-type material, a conduction band of the channel is lower than that of the organic photoelectric conversion element, and a valence band of the channel is lower than that of the organic photoelectric conversion element, on the basis of a vacuum level.

7. The photocharge storage element of claim 1, further comprising an electrode disposed on the organic photoelectric conversion element,
wherein the organic photoelectric conversion element comprises a plurality of organic layers having different energy levels, and
the plurality of organic layers are configured to generate the photocharges based on a voltage applied between the gate electrode and the electrode, and configured to move the photocharges to the channel.

8. The photocharge storage element of claim 7, wherein the electrode is used as a cathode when photoelectrons among the photocharges generated in the plurality of organic layers are collected in the channel, and
the electrode is used as an anode when photoholes among the photocharges generated in the plurality of organic layers are collected in the channel.

9. The photocharge storage element of claim 1, wherein the gate electrode, the gate insulator, the source electrode, the drain electrode, and the channel form an organic field-effect transistor.

10. The photocharge storage element of claim 1, wherein the semiconductor substrate comprises a connecting node, and
the photocharge storage element further comprises a via configured to connect one electrode among the source electrode and the drain electrode with the connecting node.

11. The photocharge storage element of claim 1, wherein the gate insulator surrounds the gate electrode.

12. An image sensor comprising:
a pixel array;
an analog-to-digital conversion (ADC) block;
a photocharge storage element; and
a row driver configured to control an operation of the photocharge storage element,
wherein the photocharge storage element includes,
a gate electrode,
a gate insulator disposed on the gate electrode,
a source electrode,
a drain electrode,
a channel disposed on the gate insulator, and disposed between the source electrode and the drain electrode,
an organic photoelectric conversion element disposed on the channel, and configured to generate photocharges in response to light, and
an electrode disposed on the organic photoelectric conversion element.

13. The image sensor of claim 12, wherein the channel accumulates photocharges generated by the organic photoelectric conversion element based on a first voltage applied between the gate electrode and the electrode.

14. The image sensor of claim 13, wherein the photocharges accumulated in the channel are read out from the channel based on a second voltage applied between the source electrode and the drain electrode.

15. The image sensor of claim 13, wherein the photocharges accumulated in the channel are read out from the channel based on a difference between a voltage applied to one electrode among the source electrode and the drain electrode and a voltage applied to the gate electrode.

16. The image sensor of claim 12, wherein an energy band of the channel is higher than that of the organic photoelectric conversion element when the channel is formed of an N-type material, and
the energy band of the channel is lower than that of the organic photoelectric conversion element when the channel is formed of a P-type material.

17. The image sensor of claim 12, wherein when the channel is formed of an N-type material, a conduction band of the channel is higher than that of the organic photoelectric conversion element, and a valence band of the channel is higher than that of the organic photoelectric conversion element, on the basis of a vacuum level.

18. The image sensor of claim 12, wherein when the channel is formed of a P-type material, a conduction band of the channel is lower than that of the organic photoelectric conversion element, and a valence band of the channel is lower than that of the organic photoelectric conversion element, on the basis of a vacuum level.

19. A portable electronic device comprising:
an image sensor including a photocharge storage element and a row driver configured to control an operation of the photocharge storage element;
a display; and
a processor configured to control an operation of the image sensor,
wherein the photocharge storage element includes,
a gate electrode,
a gate insulator disposed on the gate electrode,
a drain electrode,
a channel disposed on the gate insulator, and
an organic photoelectric conversion element disposed on the channel, and configured to generate photocharges in response to light.

20. The portable electronic device of claim 19, wherein the photocharge storage element further comprises:
a source electrode;
a substrate including a connecting node; and
a via configured to connect one electrode among the source electrode and the drain electrode with the connecting node.
